(19) United States
(12) Patent Application Publication
(10) Pub. No.: US 2006/0254815 A1
(43) Pub. Date: Nov. 16, 2006

(54) Radiofrequency identification shielding

(76) Inventors: Thomas Ward Humphrey, Cincinnati, OH (US); Mark H. Ginocchio, St. Petersburg Beach, FL (US)

Correspondence Address: WOOD, HERRON & EVANS, LLP, 2700 CAREW TOWER, 441 VINE STREET, CINCINNATI, OH, 45202, US

(21) Appl. No.: 11/114,696

(22) Filed: Apr. 26, 2005

(51) Int. Cl. H05K 9/00

(52) U.S. Cl. 174/380; 174/377; 174/378

(57) ABSTRACT

Conductive materials, such as conductive paper, paperboard or plastic, are incorporated in a variety of known products such as luggage, file containers, bags, wrappings, stationery, men's and women's accessory clothing and other devices for carrying or storing papers and objects, so as to form a Faraday cage around the contents thereof to reduce the likelihood that those contents can be interrogated by RF-ID.

### FIELD OF THE INVENTION

The invention relates to luggage, file containers, bags, wrappings, stationery, men's and women's accessory clothing and other devices for carrying or storing papers and objects.

### BACKGROUND OF THE INVENTION

Accessory clothing such as wallets, luggage, briefcases, handbags, leather goods, and the like, are designed for carrying important papers and identification in a range of sizes, from the smallest documents such as credit cards, paper money and coins, to larger documents such as passports, to even larger documents such as standard 8.5×11 inch or A4 size papers. It is important to the owner of such documents that their content remain private, as often critical information can be pilfered from such documents. Wallets for holding smaller papers are typically designed at a size that fits in a pocket, so the owner may keep the papers therein close at hand at all times. Briefcases for carrying larger papers cannot be kept in hand at all times, and for this reason briefcases often include locks to ensure that the briefcase cannot be casually opened and the papers therein reviewed without the owner's knowledge.

Larger objects are also typically packaged and placed in containers to conceal their identity and protect their contents from theft. Consumers typically put coverings over items left in a car to prevent theft. Businesses often place products in unmarked cartons, or inside locked shipping containers, to prevent theft and/or unauthorized perusal of those products while in transit.

Radio frequency identification (RF-ID) technology is being rapidly adopted throughout the industrialized parts of the world. RF-ID utilizes “tags” comprised of an integrated circuit having data storage thereon, coupled to an antenna for receiving and transmitting radio signals. Tags may be active, i.e., they may have a power supply such as a battery, or may be passive, i.e., they may have no internal power supply but instead draw operating power from the RF irradiation of the tag by an interrogator. In either case, RF-ID tags are attractive for many identification purposes because they can be read from short distances without physical contact or line-of-sight visibility of the tag to the interrogator. In manufacturing and inventory control applications RF-ID tags may be placed on inventory items so that thus items may be tracked and cataloged throughout the manufacturing, distribution and retail sales process. Owing to the conveniences of RF-ID inventory management, retailers have begun to mandate the inclusion of RF-ID tags in products of their manufacturer vendors.

RF-ID is also now being proposed for use in document and file tracking. Organizations with large numbers of paper files have contemplated tagging each file with an RF-ID tag, or even tagging each document, for tracking and identification purposes. Furthermore, Governmental institutions have begun considering including RF-ID tagging in Government identification documents; specifically, the United States Government has recently announced intentions to include RF-ID tags in all United States passports, and there are likely to be other countries that include such information in passports or other identity documents. The use of RF-ID in citizenship identification papers has several advantages, including accuracy and speed in passing individuals through immigration, and preventing counterfeiting of citizenship identification papers. However, several public commentators have expressed concern over the loss of privacy to persons carrying such documentation, noting that citizenship identification papers must be carried during international travel, and thus persons having RF-ID tags in such papers must place themselves at risk of identity theft by unscrupulous persons who can acquire an RF-ID reader and position themselves adjacent to doors or hallways where travelers carrying RF-ID documentation are likely to pass.

In connection with the privacy risks caused by RF-ID on passports, two proposals have been made by privacy advocates. One is to destroy the RF-ID chip on the passport as soon as it is received. This proposal is not believed to be practical, and may prevent the use of the passport for identification. The second proposal has been that travelers use a metal passport case when carrying the passport, with the objective of forming a Faraday cage around the RF-ID chip to block RF-ID interrogation of the passport. This second proposal is likely to work if the metal case forms a suitably conductive barrier completely surrounding the RF-ID chip, but is likely to be inconvenient for a traveler, as the metal case is likely to be bulky and heavy.

### SUMMARY OF THE INVENTION

While privacy concerns relating to U.S. passports have been documented, not all of the privacy concerns that arise from the use of RF-ID in passports have been well explained. The main concern raised has related to the privacy risks to travelers at airports, but this is not the only location where such risks arise. For example, foreign travelers are often required to obtain visas through the local embassy or consulate of the foreign country to which they will travel, and thus must carry their citizenship identification to those locations, not merely to airports. Thus, there is another location at which an unscrupulous RF-ID interrogation creates a privacy risk. Furthermore, frequent international travelers often use visa agencies to manage the process of acquiring visas; this process involves transmitting identification documents and granted visas through the mails or courier services to and from the visa agency, thus creating another risk of RF-ID privacy invasions in the mails—particularly in the mail bags and courier packages that are routed to and from a visa agency. In addition, while traveling, rental car agencies and other similar businesses may require a traveler to leave their passport with the agency as a security deposit, creating another risk of intrusion while a passport is on deposit at such a business.

There are other privacy risks of RF-ID that as yet have not been highlighted. For example, the use of RF-ID on goods substantially increases the risks of industrial espionage, e.g., the contents of a container in shipment can be readily inventoried by a competitor without physical access to those contents. And, the information that can be obtained via RF-ID is likely to be of far greater interest in industrial espionage than that which can be obtained by physical review of the contents of a container; it may be possible to obtain serial numbers and model identifiers, and from that identify manufacturing quantities of a competitor; it may further be possible to obtain shipping information such as bill of lading contents or customer names and thus determine customers and quantities shipped to customers; all of which is highly sensitive information and a frequent target of industrial espionage activities. Furthermore, RF-ID may aid thieves in identifying containers that have the most valuable merchandise and thus which are the best target for hijacking.

The purchaser of an RF-ID tagged good also has risks of identification of those goods after the purchase has been completed. For example, RF-ID tagged goods may be identified while hidden from view in a car or in the mails. This raises the possibility, for example, that would-be thieves can identify those cars or packages that have valuables, and break into those cars or packages. Furthermore, more sophisticated thieves may capture serial number information from products or discarded packaging using RF-ID, to redirect warranties or rebates.

If RF-ID were used in automobiles in conjunction with VIN numbers, or on vehicle registration documents, such devices may become a target of identity thieves, e.g., wishing to change the VIN of a stolen vehicle to enable its resale and prevent recovery. Here again, the existence of RF-ID on the vehicle or associated documents presents a privacy vulnerability to any passerby with a compatible RF-ID interrogator.

Similarly, RF-ID tagged documents and files may reveal confidential or privileged information, useful for industrial espionage or in aiding would-be thieves in locating such documents.

The proposal to use a metal case for a passport is not practical for any of these situations. Even for the passport application, the use of a metal case is impractical when the passport or other citizenship identification must be sent through a mail or courier service to and from a visa agency. More generally, metal cases are impractical for protecting larger RF-ID tagged items such as files, 8.5×11 or A4 documents, products in production, transit, purchased at retail, and the like.

There is thus an emerging need for a practical solution for reducing privacy risks inherent in the use of RF-ID on passports, other documents, files, retail products and the like.

In accordance with principles of the present invention, this need is met through the use of conductive materials, such as conductive paper, paperboard or plastic, in a variety of known products such as luggage, file containers, bags, wrappings, stationery, men's and women's accessory clothing and other devices for carrying or storing papers and objects, so as to form a Faraday cage around the contents thereof to reduce the likelihood that those contents can be interrogated by RF-ID.

For example, a pliable conductive sheet may be incorporated into a passport wallet, so that a passport in the wallet is enclosed in a conductive barrier and thus at least partially shielded from external RF-ID interrogation. Because conductive plastic or paper sheets may be pliable, they may be incorporated into a passport wallet without substantial modification thereof. Indeed, a conductive plastic may be made transparent, and thus used in a typical window pocket of a passport wallet, shielding the passport from RF-ID interrogation while still permitting visual review of the passport's contents.

In alternative embodiments, conductive plastics or papers or other conductors may be incorporated into a variety of other products such as wallets; purses; shopping bags; gift or package wrapping papers; mail bags; briefcases; file folders including expandible file folders or paper file folders (such as file folders having a closure flap fitted with a clasp such as is often used for carrying papers in interoffice mail); and stationery of various kinds including letter sized envelopes, larger clasp or adhesive closure envelopes, and courier service letter envelopes and packages. In each case the conductive plastic may be wholly or partly transparent or translucent where a window pocket is included in existing products of these types.

In a further aspect of the invention, conductive material may be incorporated into adhesive-carrying sheets, similar to those popularized in notepads. The entire sheet may be of conductive material or the sheet may have a multi-part structure, one part of which is conductive. The sheet has sufficient adhesive to be secured over the top of an RF-ID tag and/or antenna on a passport or other document, to shield the same from interrogation. Typically an adhesive carrying sheet would be adhered to both the front and back sides of that section of the document carrying the RF-ID tag and/or antenna to form a Faraday cage around the tag and/or antenna, but use on only one side is also contemplated. Here again, the sheet may be wholly or partly transparent or translucent to permit visual review of the document beneath the conductive sheet.

Another aspect of the invention features an RF-ID jamrner or disabler. The jammer is usable in locations where the use of RF-ID is to be precluded, such as on loading and shipping docks, and file or product storage areas. The jammer can be enabled except when legitimate RF-ID activity is being undertaken in the protected area. The jammer emits RF-ID radio signals on the frequency normally used by an RF-ID interrogator, creating interference that prevents an interrogator from reading the tags. The disabler is useable whenever RF-ID tags are no longer of use, and simply destroys or disables the tags by either destroying internal circuits through excess applied power, or by damaging, corrupting or erasing the tag memory.

The above and other objects and advantages of the present invention shall be made apparent from the accompanying drawings and the description thereof.

### BRIEF DESCRIPTION OF THE DRAWING

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 is an envelope incorporating conductive material;

FIG. 2 is an oversized envelope incorporating conductive material;

FIG. 3 is an alternative oversized envelope incorporating conductive material;

FIG. 4 is a courier package incorporating conductive material;

FIG. 5 is an alternative courier package incorporating conductive material;

FIG. 6 is a passport wallet incorporating conductive material;

FIG. 7 is a package wrapped with a wrapping incorporating conductive material;

FIG. 8 is a package with an RF-ID tag covered by an adhesive-backed sheet incorporating conductive material;

FIG. 9 is a document with an RF-ID tag that has been enclosed on its front and back sides by adhesive-backed sheets incorporating conductive material;

FIG. 10 is a government-originated document with an RF-ID tag that has been enclosed in the manner shown in FIG. 9;

FIG. 11 is a briefcase incorporating conductive material;

FIG. 12 is an expandible file folder incorporating conductive material;

FIG. 13 is a purse or carry-on bag incorporating conductive material;

FIG. 14 is a wallet incorporating conductive material;

FIG. 15 is a filing cabinet incorporating, or having a drawer or compartment therein incorporating conductive material;

FIG. 16 is a conductive tarpaulin that may be draped over or surrounding a product container bearing an RF-ID tag during storage or shipment; and

FIG. 17 is a conductive drapery that may be closed over a window to protect RF-ID tags within a protected space.

### DETAILED DESCRIPTION OF SPECIFIC EMBODIMENTS

RF-ID systems operate in several frequency bands, the exact frequencies being controlled by various regulatory bodies in each country. The frequencies typically used for RF-ID include 125-134 kHz, 13.56 MHz, UHF frequencies in the range of 400-930 MHz (most typically 400 MHz and 860-930 MHz), 2.45 GHz and 5.8 GHz. Many of these frequencies are also used for wireless networking, cordless telephones and the like. The various bands have advantages and disadvantages. The lower frequencies at 125-134 kHz and 13.56 MHz are said to work better near water or humans (human bodies are mostly water) than do higher frequencies. However, the lower frequencies typically have shorter range and a slower data rate. Higher frequencies are typically subject to tighter regulatory controls and more variances from country to country. In the United States, there are governmental restrictions on radiated power, established by the NIOSH (National Institute for Occupational Safety and Health), generally set in terms of mW per square centimeter of irradiation.

According to principles of the present invention, RF-ID interrogation of tagged papers or products is blocked by forming a Faraday cage of conductive material(s) surrounding the object. As noted briefly above, a Faraday cage may be formed around an object to shield the object from radio frequency irradiation, and thus block or hamper RF identification of the object. The effectiveness of a Faraday cage in blocking RF penetration is a function of several factors, including the frequency of the electromagnetic waves that are to be blocked, the power levels of those waves, and the size of any gaps in the enclosure that forms the Faraday cage. As used herein, a Faraday cage refers to any conductive enclosure that has the effect of attenuating penetration of radio frequency electromagnetic waves at some frequencies of interest to RF identification, even though such attenuation may be incomplete or may be of limited effect at other frequencies.

Typically to form a Faraday cage that is effective in attenuating a given wavelength of electromagnetic radiation, the cage must enclose the protected object sufficiently that there are no gaps in the enclosure having a smallest dimension larger than half of the wavelength of the radiation being attenuated. Greater attenuation can be achieved if there are no gaps in the enclosure having a largest dimension smaller than half of the wavelength of the radiation being attenuated, and/or if any gaps in the enclosure have highly conductive paths around their perimeter. A Faraday cage may be formed of solid conductive walls or of walls having apertures such as a screen, so long as those apertures are no larger than approximately half of the wavelength of the radiation to be blocked. (The wavelength of radiation may be computed by dividing the frequency of the radiation into the speed of light, which in air is approximately 3×10⁸ meter/second. Thus 13.56 MHz radiation has a wavelength of about 20 meters.)

For the purposes of blocking or reducing RF-ID at frequencies below 1 GHz, an adequate Faraday cage may be formed even where there are gaps as large as 10 cm in the enclosure. Thus an effective Faraday cage can be formed by a typical business or interoffice envelope, despite the existence of non-airtight gaps in the closure of the envelope, as those gaps will be relatively small. Similarly, a wallet pocket for carrying a credit card or passport can form an effective Faraday cage even though there may be some small gaps at the opening of the pocket or around the sides of the pocket, as those gaps will be relatively small

It will be appreciated that RF frequencies used for RF-ID have expanded into additional bands in the past and will continue to do so, and the invention is applicable in any frequency band, specific bands being identified here for exemplary purposes only.

In accordance with principles of the present invention, conductive material(s) form a Faraday cage embedded into various luggage, wallet and other items. A Faraday cage may be created using metals or non-metallic conductors such as pliable conductive materials, e.g., conductive plastics and conductive papers. Conductive plastics and papers are well known in the art, and are typically formed by coating a substrate with conductive materials such as Aluminum, and/or embedding conductivity inducing materials, such as carbon black or amines, into the plastic or fiber substrate. U.S. Pat. No. 5,613,610 to Bradford, which is hereby incorporated herein by reference, describes a permanently static dissipative material formed of cellulose that is also biodegradable, as well as describing carbon-black impregnated paperboard. U.S. Pat. No. 4,658,985, to McNulty, which is hereby incorporated by reference, describes bags of polyethylene material with embedded conductive fabrics or mats. U.S. Pat. No. 4,623,594 to Keough, which is hereby incorporated by reference, describes a mixture of prepolymer and anti-static agent that may be applied to a substrate, such as polypropylene fiber or paper or glass, and then cured to the anti-static agent by contacting the mixture with electron beam radiation. U.S. Pat. No. 4,606,790 to Youngs et al., which is hereby incorporated by reference, describes a conductive paperboard made as such by the inclusion of carbon-black.

Various industry standards have been established relative to conductive plastics and conductive materials, including specifically military standard MIL-PRF-81705D, which is hereby incorporated by reference herein. This military standard establishes standards for conductive packaging typically used for protecting static-sensitive components from electrostatic discharges. This military standard defines a Type III material, typically having a 100 ohm per square surface resistance, which is generally effective for reduction of 90% or better of RF energy impinging upon the material. Type III plastic material is typically translucent, that is, any coatings thereon are not typically at such a thickness as to prevent passage of light through the plastic. This military standard also defines Type I material, typically having a 1 ohm per square surface resistance, generally effective for reduction of electromagnetic radiation to a substantial extent, i.e., by −25 dB or by a factor of about 300. Type I material is often opaque owing to the thickness of coatings thereon. For extreme shielding, copper or silver may be used, and achieve reductions in radiation of up to 64 dB, but for typical applications at frequencies below 10 GHz, Aluminum coated, closed enclosures, are typically sufficient for preventing substantial RF penetration.

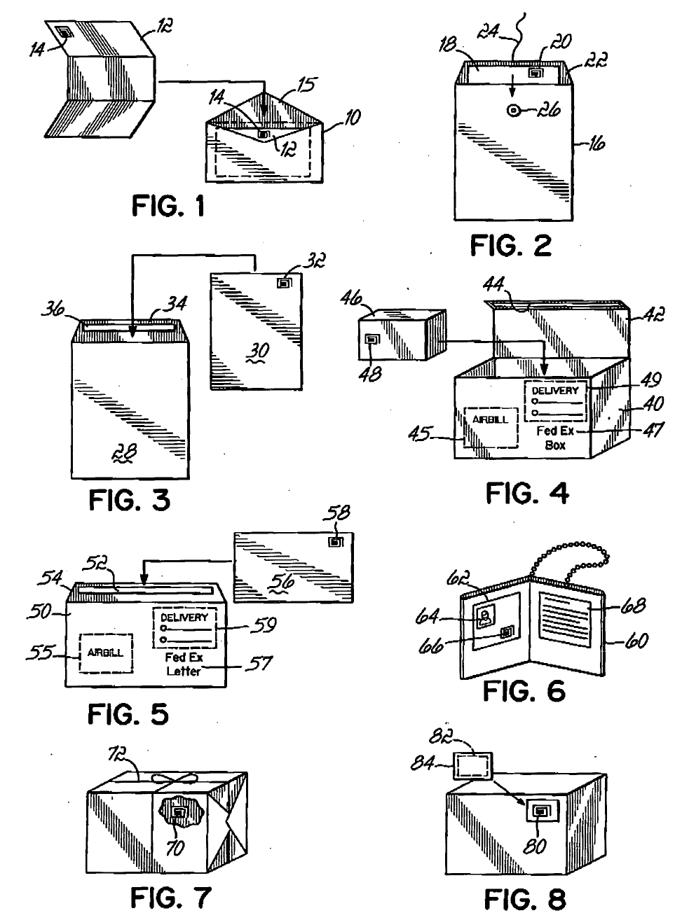

Turning to FIG. 1, a first embodiment of the invention is illustrated in which a standard business sized envelope 10 is formed of a conductive paper, conductive plastic material, a combination thereof or other conductive material. Envelope 10 is sized to receive a tri-folded standard business letter of size 8.5×11 inches, A4 or other standard sizes. The document 12 contains an RF ID tag 14 the contents of which are to be maintained secure by placement into envelope 10. For similarity to known products, envelope 10 may be made of pliable conductive material. When document 12 is inserted into envelope 10 and flap 15 is closed, envelope 10 forms a Faraday cage enclosing document 12 and shielding RF ID interrogation thereof.

Referring now to the FIG. 2, in accordance with the second embodiment of the invention an interoffice clasp style envelope is utilized as a Faraday cage shield. Envelope 16 is again formed of a conductive material, and is sized to receive a standard business sized document 18 bearing an RF ID tag 20. Flap 22 connected to envelope 16 is closed over the opening of envelope 16 to form a Faraday cage, effective in shielding RF ID interrogation of tag 20. The closure of envelope 16 may take any variety of forms, such as clasps or clips or, as illustrated, a string 24 to be wrapped about a closure bobbin 26.

Referring FIG. 3, yet another embodiment of the invention is an envelope 28 formed of conductive pliable material, sized for receipt of a standard business document 30 bearing an RF ID tag 32. In this instance, envelope 28 has a flap 34 which bears an adhesive 36. Adhesive 36 may be a conductive adhesive so that an effective conductive connection is made between flap 34 and the body of envelope 28 when adhesive 36 is adhered to close flap 34. Conductive adhesives may also be used another sizes and styles of envelope such as the envelope of FIG. 1. Conductive adhesive may, or may not, be used, as needed for a particular level of shielding, and/or as needed to general customer appeal.

Referring now to FIG. 4, and in accordance with another embodiment of invention, a shipping container, such as are commonly used by courier services, is formed of non-metallic pliable conductive material, in this case rigid conductive cardboard. Conductive cardboard or stiff conductive plastic may be utilized effectively, as the shipping container is designed to have some measure of rigidity. Advantageously, parcel container 40 may be made available by the courier service, ready for labeling and shipment, as is presently done for nonconductive containers. Again container may have a flap 42 bearing a conductive adhesive in area 44 for sealing the container. A courier service customer's parcel 46 bearing an RF ID tag 48 may be placed in container 40 in a conventional manner, and the container when sealed will form not only a physical protection for the item 46 but also form Faraday cage about the item 46 preventing RF ID interrogation thereof.

Referring now to FIG. 5, a flat letter sized envelope 50 bearing a conductive or standard adhesive 52 on a flap 54 may also be provided by or for use with a courier service. Here the envelope 50 is formed of a pliable or rigid conductive material to shield a document or pack of documents 56 bearing an RF ID tag 58, by a Faraday cage effect.

Referring to FIGS. 4 and 5 will be noted that the box shown in FIG. 4 and the envelope show in FIG. 5 differ from known conductive cardboard packaging in that each carries a courier service identifier label in the area 47 and 57, and also carries additional information relating to the services of a courier service in area 49 and 59, such as information on various delivery options and weight limitations. Furthermore, these conductive packages include an area 45 and 55 sized for placement of a courier service air bill. While conductive packages have been known and used for shipping electronic components, those packages are not sized and labeled appropriately for use as a standard parcel package of a common courier service, such as the services branded with the trademarks FedEx, Airborne, UPS, DHL, and the like. Known conductive packaging is not so printed and arranged for common carrier use, and known packaging that is so printed and arranged for common carrier use, is not conductive. It is believed that a significant competitive advantage can be afforded to a courier service offering a conductive package and/or several conductive packaging options to customers, as such packaging will come into demand once customers become aware of the privacy invasion threats incumbent upon the use of RF identification in passports and other documents and objects.

Referring to FIG. 6, pliable conductive material may be incorporated into accessory clothing such as leather goods or wallets. As illustrated in FIG. 6 a passport wallet 60 may be lined with or formed of in part of conductive materials such as conductive paperboards or plastics, to protect a passport 62 therein from RF ID interrogation. As shown, the passport may contain a photograph 64 as well as an RF ID tag 66. Furthermore, another surface of passport 62 may include VISAs or other markings of interest in area 68. Many passport wallets are designed such that these markings and also the photograph 64 are visible, even while the passport is retained within the wallet. This may also be accomplished when the wallet is made of conductive material so long as that conductive material is translucent in part, such as may be accomplished using conductive plastics for window material.

Referring now to FIG. 7, an alternative embodiment of the invention, applicable to a wide variety of possible package sizes carrying RF identification, is illustrated. As shown FIG. 7, a parcel containing an RF ID tag 70 may be packaged for shipment in a way that protects the privacy of information on the RF ID tag 70. Specifically, a pliable conductive material, e.g. conductive plastic or conductive paper or paperboard, is utilized as wrapping paper for the package, thereby enclosing the entire package in a conductive Faraday cage. As shown in FIG. 7 the wrapping paper or plastic which is folded about the package may then be taped closed as is conventionally done in gift wrapping, tied with a ribbon 72 as is done with gift wrapping and parcel wrapping, or may be closed by other means. Conductive tapes or adhesives may be advantageously used in closing the wrapping about the package. An effective Faraday cage shielding RF ID tag 70 from interrogation can be formed in this way regardless of the size of packages.

FIG. 16 illustrates an alternative of this concept in which a conductive tarpaulin 74 is draped over a package bearing an RF-ID tag 70 to shield the tag from interrogation while the package is in storage or shipment.

Referring to FIG. 8, yet another alternative embodiment of the invention can be disclosed. In this embodiment a package carrying an RF ID tag 80 is shielded from RF identification by the use of a conductive sheet 82, e.g., a sheet of metallic, of paper or plastic material that is rendered adhesive by a layer of adhesive attached to one side thereof in the area 84. By attaching the conductive sheet 82 over the RF ID tag 80, a measure of immunity to interrogation may be provided to RF ID tag 80.

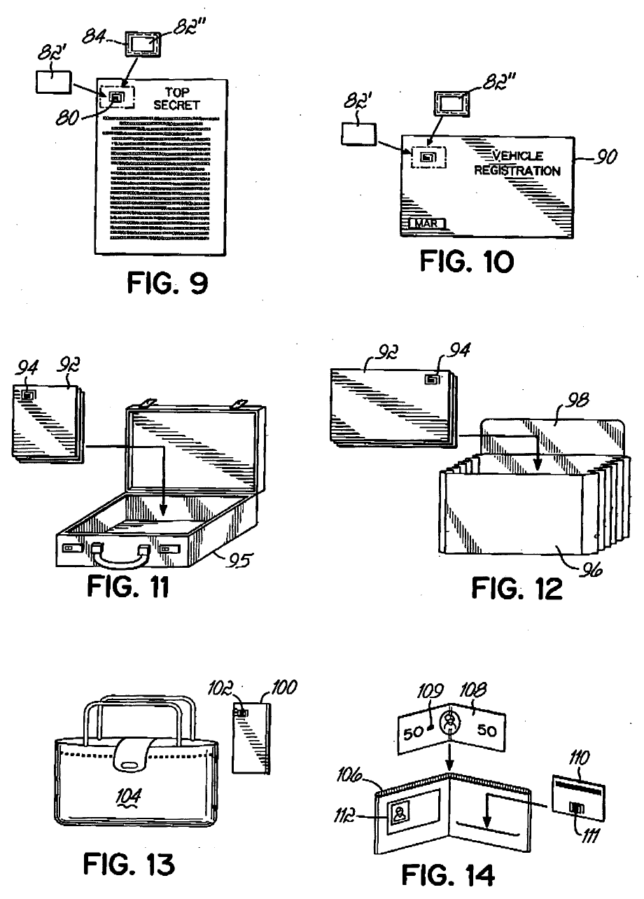

Referring to FIG. 9, conductive sheets 82 bearing adhesive in areas 84 may also be used to encapsulate an RF ID tag 80, found on a document or other thin item. Specifically, a first sheet 82′ is placed on the front side of the document or thin item covering the RF ID tag 80, and the second sheet 82″ is placed on the rear side of the document or thin item so that in combination the sheets 82′ and 82″ form a Faraday enclosure surrounding the RF ID tag and decreasing the susceptibility thereof to interrogation. The adhesive sheets utilized in this manner may take on a variety of sizes and shapes, ranging from a sufficient size to encapsulate an entire document such as an 8.5×11 or A4 sized sheet, to a smaller size that matches to the size of the RF ID tag to be shielded from interrogation. FIG. 10 illustrates an embodiment in which such sheets are relatively small in size and designed to fit over an RF ID tag on a vehicle registration certificate 90. Vehicle registration certificate 90 is of the kind that would be typically found in the glove compartment of a car, and would be desirably protected from unwanted RF ID interrogation. A combination of suitably sized RF ID shielding sheets 82 could be advantageously used in such an environment to shield the vehicle registration tag from unwanted interrogation.

This embodiment of the invention utilizing adhesive bearing sheets may utilize conductive paper or conductive plastics. Conductive paper adhesive bearing sheets may advantageously be used for note taking as well as for RF ID shielding. Conductive plastic RF ID sheets may potentially be made transparent or translucent so that they shield RF ID interrogation while still permitting visibility of the content of a document or a item beneath the adhered sheet. Thus, such sheets placed over a passport on the front and rear side of a location of RF ID tag may protect the passport RF ID tag from interrogation while permitting visual inspection of the passport by customs and security officials. The adhesive used may be conductive as well, or may be nonconductive.

Referring to the FIG. 11, another embodiment of the present invention is illustrated. FIG. 11 illustrates a bundle of papers 92 bearing one or more RF ID tags 94 to be protected from interrogation. In FIG. 11 a conventional briefcase or attaché case is lined or formed in part by conductive material, such that when the briefcase is closed it forms a conductive enclosure and a Faraday shield from interrogation of RF ID tag 94. It will be appreciated that in the past attaché cases have been made of conductive materials such as aluminum, however there has not previously been any intention to achieve RF shielding by the use of such materials. Furthermore, an attaché case made of metal may not be desirable from a fashion standpoint, and the present invention permits an attaché case to achieve a shielding function without compromise as to appearance of the attaché case or any requirement that the attaché case be made of a metallic material. A similar advantage of obtains with the passport case in FIG. 6, which may or may not be made of any metallic material, but nevertheless achieves the shielding function desired.

Referring to FIG. 12, documents or items such as document 92 bearing RF ID tag 94 may also be shielded while inside what appears to be a typical file folder, because that folder has been modified in accordance with the present invention to have a conductive property. FIG. 12 illustrates an expendable folder style folder made of a conductive paperboard, conductive cardboard or conductive plastic material. File folder 96 has a top flap 98 which may be folded over the top of folder to form a conductive enclosure and thus reduce the suceptibility of RF ID tag 94 to undesired interrogation.

Similar concepts may be implemented in accessory clothing items that have not previously been described. For example, a passport or other object 100 containing an RF ID tag 102 may be shielded when placed inside of a handbag, purse or carry-on bag 104. If, in accordance with principles of the present invention, the handbag or purse is lined with or formed partially of conductive material such as pliable conductive paper or conductive plastic, closing the bag about an object may form a Faraday cage and shield the object from unwanted interrogation. The same principle may be applied to other soft or hard sided luggage, not limited to briefcases and handbags as shown in FIGS. 11 and 13.

Referring now to FIG. 14, other accessory clothing for pockets may also be enhanced in accordance with principles of the present invention to provide RF ID shielding. Specifically, a man's or woman's wallet 106 may be lined or formed partially of conductive paperboard or plastics such that currency notes 108 placed therein and/or credit cards or other identification 110 placed therein are shielded from undesired RF identification due to the shielding effect of the Faraday cage formed by the wallet when closed about the RF ID tag 109 or 111 on the respective items. It will be noted that an RF ID shielded wallet may also contain transparent or translucent sections 112 for convenient display of identification documents or other objects used for identification that are frequently accessed in the wallet 106. In accordance with the principles of present invention a clear plastic conductive material may be utilized to form this window 112 thus providing RF ID shielding even while permitting visual inspection of the identification documents.

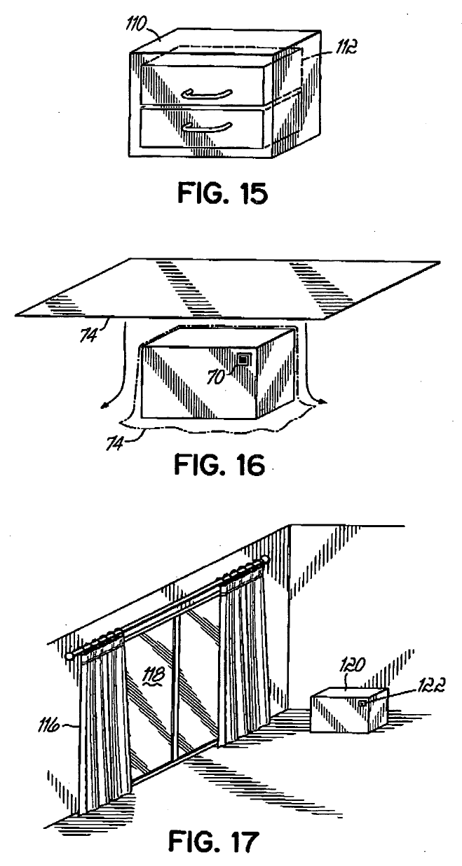

Referring now to FIG. 15, the principles of the present invention may also be applied in furniture such as office furniture or other types of furniture. FIG. 15 illustrates a file cabinet 110 which may be made from wood or another nonconductive building material, and thus provide no shielding from RF identification. Such a cabinet in accordance with principles of present invention may be lined or formed partly of conductive material thus providing a shielding function not previously provided by furniture. Here again fashion may dictate that non metallic furniture be utilized in a particular environment. The present invention permits the selection of furniture based upon such fashion considerations, while still providing a shielding function. It will be noted that an entire item of furniture may be so lined or formed for shielding, or a specific drawer or compartment 112 of the furniture may be so formed if only that drawer is to contain objects and documents that are likely to be RF ID tagged and are clearly in need of protection from unwanted interrogation.

FIG. 17 illustrates the use of a cloaking drapery 116 to protect an interior space from interrogation through a window 118. Such cloaks or draperies may be used to block potential points of entry of RF signals in metal buildings that are otherwise inherently shielding. In building structures that are not inherently shielding (e.g., wood frame) such cloaks may be used to cordon a portion of the building such as a room or secure area to reduce the likelihood of unwanted interrogation. Such cloaks can be permanently installed or temporary, much as room dividers and cubicles are used in industrial buildings at the present time. Cloaks or temporary cloaking screens can be set upon racking, or hung on walls.

In an alternative embodiment, windows may be cloaked by conductive plastic films of the types earlier described, which can be opaque, translucent or transparent. Such may be used for shielding in offices, hotels and private homes.

A further alternative embodiment of the invention involves the use of conductive paints or other liquids that can be used to form a conductive Faraday cage barrier around an object to be protected; e.g., a clear coat of conductive material may be coated over a tag or over an enclosing envelope or wrapping containing a tagged document or object.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. The invention in its broader aspects is therefore not limited to the specific details, representative apparatus and method, and illustrative example shown and described. Accordingly, departures may be made from such details without departing from the spirit or scope of applicant's general inventive concept.

What is claimed is:

1. An item of luggage, file container, or accessory clothing item comprising a compartment sized for holding a passport and shielded from radio frequency radiation, the shielded compartment being lined with a pliable conductive material.

2. An item of luggage according to claim 1 wherein said item is arranged to facilitate handling by third parties.

3. An item of luggage according to claim 1 wherein said compartment is sized for holding sheets of paper.

4. An accessory clothing item according to claim 1 wherein said item is a passport wallet and said wallet primarily comprises said compartment sized for holding a passport.

5. The item of luggage, file container or accessory clothing item of claim 1 wherein said pliable conductive material is at least in part translucent.

6-25. (canceled)

26. An enclosure for a document or object bearing an RF-ID tag, the enclosure arranged to permit for temporary delivery thereof to a third party for transportation or handling while shielding the RF-ID tag from interrogation, the enclosure comprising a compartment shielded from radio frequency radiation, the shielded compartment being lined with a pliable conductive material

27. The enclosure according to claim 26 wherein said compartment is sized for holding a passport.

28. The enclosure according to claim 26 wherein said compartment is sized for holding sheets of paper.

29. The enclosure according to claim 26 wherein said enclosure is a passport wallet and said compartment is sized for holding a passport.

30. The enclosure of claim 26 wherein said pliable conductive material is at least in part translucent.

31. A method of shielding an RF-ID tag and/or antenna from interrogation during second party handling, comprising
enclosing said RF-ID tag and/or antenna within an enclosure comprising a compartment shielded from radio frequency radiation,
delivering said enclosure containing said tag and/or antenna from a first party to a second party for handling,
retrieving said enclosure containing said tag and/or antenna from said second party to said first party, and
removing said RF-ID tag and/or antenna from said enclosure.

32. The method according to claim 31 wherein said RF-ID tag and/or antenna are part of a passport, and said compartment is sized for holding a passport.

33. The method according to claim 31 wherein said compartment comprises pliable conductive material.

34. The method according to claim 32 wherein said compartment comprises pliable conductive material.

35. The method according to claim 34 wherein said pliable conductive material is at least in part translucent and placing said passport within said compartment comprises positioning said passport to be visible through said translucent pliable conductive material.
